(19) United States
(12) Patent Application Publication
(10) Pub. No.: US 2026/0333914 A1
(43) Pub. Date: Oct. 22, 2026

(54) IMAGE SENSOR DEVICE WITH LIGHT RETENTION STRUCTURE

(71) Applicant: Taiwan Semiconductor Manufacturing Company, Ltd., Hsinchu (TW)

(72) Inventors: Cheng-Yu Huang, Hsinchu (TW); Keng-Yu Chou, Kaohsiung City (TW); Yi-Hsuan Wang, Hsinchu City (TW); Wei-Chieh Chiang, Yuanlin Township (TW)

(21) Appl. No.: 19/721,016

(22) Filed: Jun. 26, 2026

Related U.S. Application Data
(63) Continuation of application No. 18/401,751, filed on Jan. 2, 2024.
(60) Provisional application No. 63/607,124, filed on Dec. 7, 2023.

(51) Int. Cl. H10F 39/00

(52) U.S. Cl. CPC H10F 39/8063; H10F 39/024

(57) ABSTRACT

Some embodiments relate to an integrated circuit device including a semiconductor layer, a pixel including a photodetector in the semiconductor layer, a conductive structure electrically coupled to the pixel on a first side of the semiconductor layer, a plurality of light diffusors overlying the photodetector on a second side of the semiconductor layer opposite the first side, and a light-focusing structure overlying the plurality of light diffusors. The light-focusing structure includes a plurality of light-focusing portions. Each of the plurality of light-focusing portions overlies, and is configured to focus light on, a corresponding one or more of the plurality of light diffusors.

### REFERENCE TO RELATED APPLICATIONS

This Application is a Continuation of U.S. application Ser. No. 18/401,751, filed on Jan. 2, 2024, which claims the benefit of U.S. Provisional Application number 63/607,124, filed on Dec. 7, 2023. The contents of the above-referenced Patent Applications are hereby incorporated by reference in their entirety.

### BACKGROUND

In some image sensors, such as single-photon avalanche diode (SPAD) image sensors and complementary metal-oxide-semiconductor (CMOS) image sensors (CIS), light detection is based on absorption of photons within a semiconductor (e.g., silicon) photosensitive region that functions as a portion of a photodetector of a pixel. Such detection may be more challenging in near-infrared (NIR) imaging applications due to a reduced absorption of photons in the photosensitive region in the NIR wavelength band, possibly resulting in low light sensitivity and poor image quality.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic isometric view of some embodiments of an image sensor IC device, according to the present disclosure.

FIGS. 1B and 1C illustrate schematic cross-sectional and top views, respectively, of some embodiments of a single-pixel image sensor structure employable in the image sensor IC device of FIG. 1A, according to the present disclosure.

FIGS. 2A and 2B illustrate cross-sectional and top views, respectively, of some embodiments of a single-pixel image sensor structure employing a three-by-three array of single pyramidal diffusor structures, a low-refractive-index grid, and an array of microlenses, according to the present disclosure.

FIGS. 3A and 3B illustrate cross-sectional and top views, respectively, of some embodiments of a single-pixel image sensor structure employing a two-by-two array of single pyramidal diffusor structures, a low-refractive-index grid, and an array of microlenses, according to the present disclosure.

FIGS. 4A and 4B illustrate cross-sectional and top views, respectively, of some embodiments of a single-pixel image sensor structure employing a three-by-three array of rotated single pyramidal diffusor structures, a low-refractive-index grid, and an array of microlenses, according to the present disclosure.

FIGS. 5A and 5B illustrate cross-sectional and top views, respectively, of some embodiments of a single-pixel image sensor structure employing a three-by-three array of laterally-shifted single pyramidal diffusor structures, a low-refractive-index grid, and an array of microlenses, according to the present disclosure.

FIGS. 6A and 6B illustrate cross-sectional and top views, respectively, of some embodiments of a single-pixel image sensor structure employing a three-by-three array of multiple pyramidal diffusor structures, a low-refractive-index grid, and an array of microlenses, according to the present disclosure.

FIGS. 7A and 7B illustrate cross-sectional and top views, respectively, of some embodiments of a single-pixel image sensor structure employing a two-by-two array of multiple pyramidal diffusor structures, a low-refractive-index grid, and an array of microlenses, according to the present disclosure.

FIGS. 8A and 8B illustrate cross-sectional and top views, respectively, of some embodiments of a single-pixel image sensor structure employing a three-by-three array of single pyramidal diffusor structures and an array of microlenses, according to the present disclosure.

FIGS. 9A and 9B illustrate cross-sectional and top views, respectively, of some embodiments of a single-pixel image sensor structure employing a three-by-three array of single pyramidal diffusor structures and a low-refractive-index grid, according to the present disclosure.

FIGS. 10A and 10B illustrate cross-sectional and top views, respectively, of some embodiments of a single-pixel image sensor structure employing a three-by-three array of multiple columnar diffusor structures, a low-refractive-index grid, and an array of microlenses, according to the present disclosure.

FIGS. 11A and 11B illustrate cross-sectional and top views, respectively, of some embodiments of a single-pixel image sensor structure employing a three-by-three array of single columnar diffusor structures, a low-refractive-index grid, and an array of microlenses, according to the present disclosure.

FIGS. 12A and 12B illustrate cross-sectional and top views, respectively, of some embodiments of a single-pixel image sensor structure employing a three-by-three array of rotated single columnar diffusor structures, a low-refractive-index grid, and an array of microlenses, according to the present disclosure.

FIGS. 13A and 13B illustrate cross-sectional and top views, respectively, of some embodiments of a single-pixel image sensor structure employing a three-by-three array of single pyramidal diffusor structures and an array of meta-lenses, according to the present disclosure.

FIGS. 14A and 14B illustrate cross-sectional and top views, respectively, of some embodiments of a single-pixel image sensor structure employing a three-by-three array of single pyramidal diffusor structures and an array of Fresnel lenses, according to the present disclosure.

FIGS. 15A and 15B illustrate cross-sectional and top views, respectively, of some embodiments of another single-pixel image sensor structure employing a three-by-three array of single pyramidal diffusor structures and an array of meta-lenses, according to the present disclosure.

FIGS. 16A and 16B illustrate cross-sectional and top views, respectively, of some embodiments of another single-pixel image sensor structure employing a three-by-three array of single pyramidal diffusor structures and an array of Fresnel lenses, according to the present disclosure.

FIGS. 17A and 17B illustrate cross-sectional and top views, respectively, of some embodiments of a single-pixel image sensor structure employing a three-by-three array of single pyramidal diffusor structures, a low-refractive-index grid, and an array of meta-lenses, according to the present disclosure.

FIGS. 18A and 18B illustrate cross-sectional and top views, respectively, of some embodiments of a single-pixel image sensor structure employing a three-by-three array of single pyramidal diffusor structures, a low-refractive index grid, and an array of Fresnel lenses, according to the present disclosure.

FIGS. 19A and 19B illustrate cross-sectional and top views, respectively, of some embodiments of a single-pixel image sensor structure employing a partially empty three-by-three array of multiple columnar diffusor structures, a low-refractive-index grid, and an array of microlenses, according to the present disclosure.

FIGS. 20A through 20K illustrate cross-sectional side views of some embodiments of an IC device including a single-pixel image sensor structure at various stages of manufacture, according to the present disclosure.

FIG. 21 illustrates a methodology of forming an IC device including a single-pixel image sensor structure, in accordance with some embodiments.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

To enhance the light sensitivity of image sensors (e.g., NIR image sensors), some such sensors include a light “trap” structure that is configured to retain an increased number of photons within the photosensitive region of a photodetector of the pixel structure to facilitate absorption of the photons therein. In some cases, a single diffusor structure may be employed across a substantial entirety of the pixel structure, thus redirecting photons as they enter the pixel structure to facilitate absorption of the photons along elongated, oblique paths created by the redirection. However, the use of the diffusor structure tends to allow the photons that have not been absorbed in the photosensitive region to exit the pixel structure via the diffusor structure due to the anti-reflection effect provided by the diffusor structure. More specifically, at least some of the redirected photons in the photosensitive region may be reflected back toward the angled surfaces provided by the diffusor structure, thus causing the photons to impact the angled surfaces nearly perpendicularly, thereby facilitating transmission of the photons back through the diffusor structure.

In other examples, a single diffusor structure may be provided only at the center of the pixel structure, and a corresponding focusing structure may focus light to the diffusor structure. While such a pixel structure may increase the number of photons retained and absorbed therewithin, for wider pixel structures that are associated with larger pixel sizes, the associated focusing structure (e.g., a lens, a low-refractive-index grid, and/or the like) is correspondingly thicker. This increased thickness of the focusing structure may pose significant challenges to the IC device fabrication process.

To address these issues, the present disclosure provides some embodiments of an IC device employing a pixel structure that includes a plurality of light diffusors and a light-focusing structure having a plurality of light-focusing portions, each of which is optically coupled with a corresponding one or more of the plurality of light diffusors.

Accordingly, use of some embodiments may provide an IC device having a photodetector of a pixel structure in which incoming light is focused to corresponding groups of one or more light diffusors, thus allowing for areas over the photosensitive region to remain uncovered by the light diffusors. Consequently, while much of the received light may be redirected to enhance photon absorption within the photosensitive region of a photodetector, less light may escape the pixel structure by way of the light diffusors, as more photons may impact surfaces between the light diffusors at angles that promote reflection (e.g., total internal reflection) back into the photosensitive region, thus increasing the overall optical path in the photosensitive region and thus improving quantum efficiency of the pixel structure. Moreover, in some embodiments, by employing the plurality of light-focusing portions of the light-focusing structure, the overall thickness or height of the light-focusing structure may be reduced, even for IC devices employing large pixels.

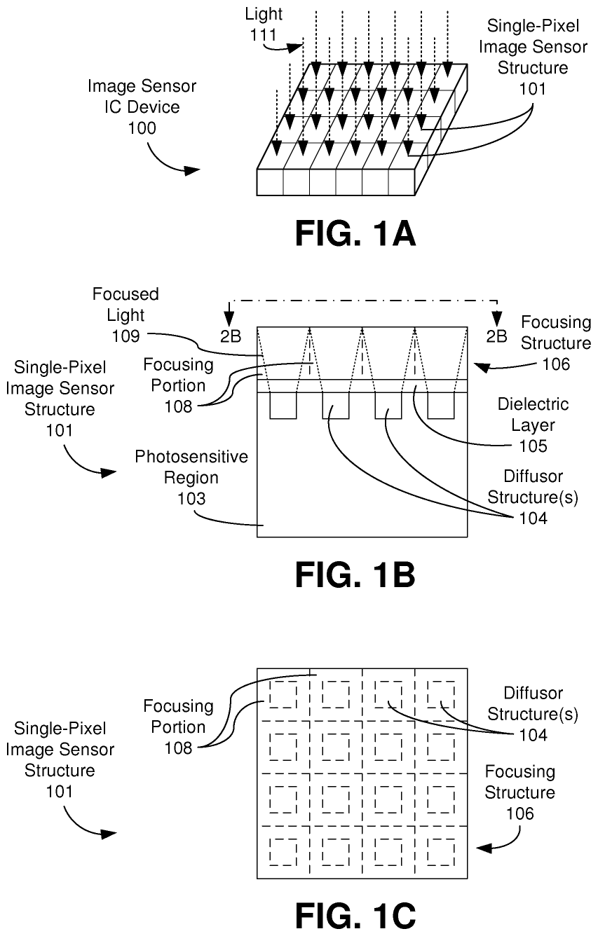

FIG. 1A illustrates a schematic isometric view of some embodiments of an image sensor IC device 100, according to the present disclosure. As shown, image sensor IC device 100 includes a plurality (e.g., an array) of single-pixel image sensor structures 101 (also referred to as pixel structures 101 below). In various embodiments discussed below, light 111 is received from above and detected by the plurality of pixel structures 101. In some embodiments, including those discussed herein, image sensor IC device 100 may be a back-side-illuminated (BSI) image sensor IC device, in which light entering a back side (or second side) of the IC device (e.g., the side opposite a front side (or first side) at which a conductive structure electrically coupled to the photosensitive regions of pixel structures 101) is detected.

FIGS. 1B and 1C illustrate schematic cross-sectional and top views, respectively, of some embodiments of a single-pixel image sensor structure 101 employable in the image sensor IC device 100 of FIG. 1A, according to the present disclosure. As illustrated, a photosensitive region 103 of a photodetector, in which photons are absorbed and detected for the particular pixel, is included. A plurality of diffusor structures 104 are disposed over photosensitive region 103. In some embodiments, the plurality of diffusor structures 104 may be arranged into groups of one or more light diffusor structures 104, examples of which are discussed in greater detail below. Also, in some embodiments, each group of diffusor structures 104 may be spaced from other groups of the diffusor structures 104 (e.g., as shown in the plan view of FIG. 1C). The portion of the light-receiving area of pixel structure 101 consumed by diffusor structures 104 may be less than 80 percent in some embodiments, less than 50 percent in other embodiments, and less than 10 percent in still other embodiments.

Over the diffusor structures 104 may be disposed a focusing structure 106, which may include a plurality of focusing portions 108. In some embodiments, each focusing portion 108 may include one or more focusing components, as discussed more fully below. Also, in some embodiments, each focusing portion 108 may overlie, and may be optically coupled to, or configured to focus light on, an associated one of the groups of diffusor structures 104 to provide focused light 109 to the associated group of diffusor structures 104.

In some embodiments, between diffusor structures 104 and focusing structure 106 may reside a dielectric layer 105. In some embodiments, dielectric layer 105 may be configured to reflect light received from below back into the photosensitive region 103. Further, in some embodiments, dielectric layer 105 may possess a dielectric constant ‘n’ that is less than that of photosensitive region 103 (e.g., silicon) to permit at least some total internal reflection (TIR) to facilitate reflection of light from photosensitive region 103 at the interface with dielectric layer 105, thus improving absorption of photons within photosensitive region 103.

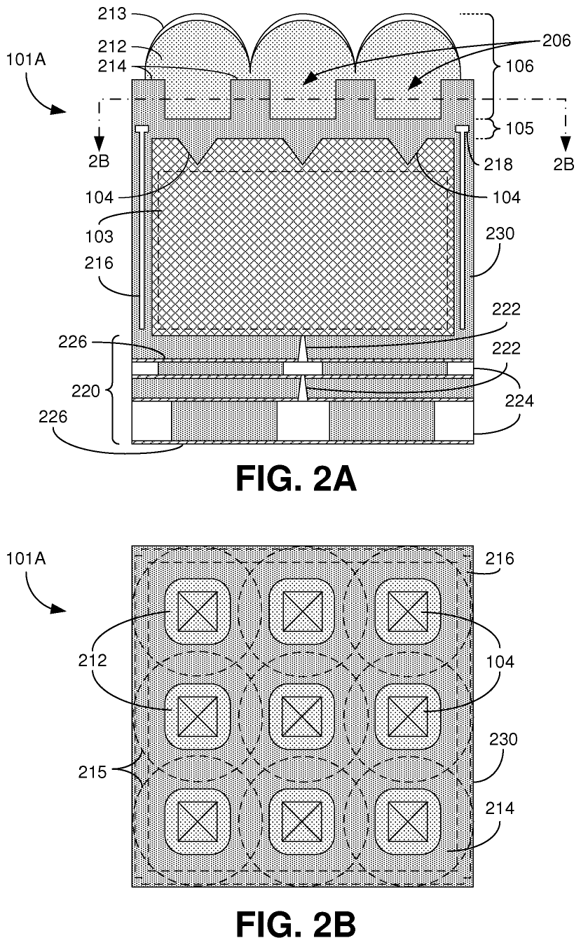

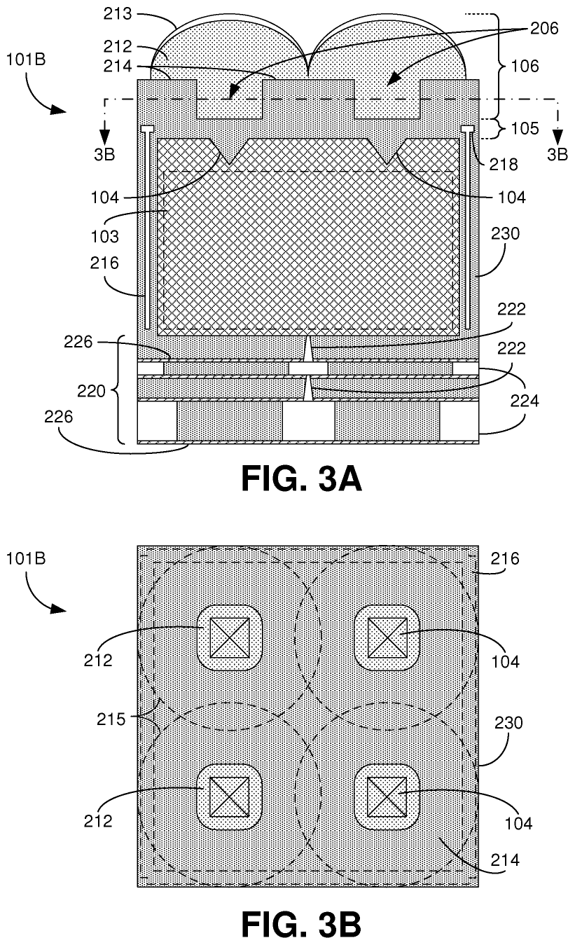

FIGS. 2A through 19B provide views of various embodiments of single-pixel image sensor structure 101, each of which is discussed below. More specifically, FIGS. 2A and 2B illustrate cross-sectional and top views, respectively, of some embodiments; FIGS. 3A and 3B illustrate cross-sectional and top views, respectively, of other embodiments; and so on. While many of the embodiments described below are directed primarily to silicon-based image sensors for NIR applications, other embodiments may be employed in germanium-based image sensors for short-wave infrared (SWIR) applications, silicon-based image sensors for visible range applications, and others.

For example, FIGS. 2A and 2B illustrate cross-sectional and top views, respectively, of some embodiments of a single-pixel image sensor structure (also referred to herein as a pixel structure) 101A employing a three-by-three array of single pyramidal diffusor structures 104, a low-refractive-index (low-n) grid (LNG) 214, and an array of microlenses (MLs) 212, according to the present disclosure. Further, as indicated in FIG. 2A, MLs 212 and LNG 214 together may constitute a focusing structure 106, where each ML 212 and associated region of LNG 214 surrounding a particular aperture 206 thereof may constitute a focusing portion 108 of FIGS. 1A and 1B. While each ML 212 is depicted as a spherical lens, other shapes of lenses for ML 212 may be employed in other embodiments. In addition, in some embodiments, an antireflective coating 213 (e.g., silicon dioxide (SiO₂)) may be disposed over MLs 212. In some embodiments, MLs 212 may have a high refractive index relative to LNG 214 (e.g., to promote TIR). Further, MLs 212 may be highly transparent with respect to the light wavelengths to be detected in photosensitive region 103. Also, in some embodiments, a dielectric layer 105 is disposed between LNG 214 and pyramidal diffusor structures 104 (e.g., to reflect light from below back into photosensitive region 103).

More specifically, as shown to best effect in FIG. 2B, a total of nine MLs 212 and nine pyramidal diffusor structures 104 may be arranged as a three-by-three array in a plan view of pixel structure 101A. In other embodiments, greater or fewer numbers of MLs 212 and pyramidal diffusor structures 104 may be employed. In addition, the overall effective footprint 215 of each ML 212 is denoted in FIG. 2B (and other figures discussed below), indicating that an overwhelming majority of the light impacting the overall area of pixel structure 101A, as shown in the plan view, is redirected by an ML 212. As also depicted in FIG. 2B, the overall area consumed by pyramidal diffusor structures 104 is significantly less than the total area of the pixel structure 101A, as discussed above in conjunction with FIGS. 1A-1C.

Each of pyramidal diffusor structures 104 has an apex directed downward (e.g., into photosensitive region 103). In some embodiments, each of pyramidal diffusor structures 104 redirects light received via MLs 212 and LNG 214 to promote photon absorption within photosensitive region 103.

LNG 214, as depicted in FIGS. 2A and 2B, may be configured with an array of apertures 206 or openings, with each aperture 206 positioned over a corresponding pyramidal diffusor structure 104 (e.g., resulting in nine apertures 206, as shown to best effect in FIG. 2B). In some embodiments, LNG 214 includes a dielectric material (e.g., silicon dioxide (SiO₂), another silicon oxide (SiOₓ), or another dielectric material), which may be the same material as dielectric layer 105. Further, in some embodiments, LNG 214 may possess a refractive index less than the refractive index of MLs 212. More specifically, in some embodiments, LNG 214 may possess a refractive index less than 1.5, while the refractive index of MLs 212 may be greater than 1.5. Thus, in some embodiments, LNG 214 may be configured to both transmit light received at a top surface of LNG 214 by way of its corresponding ML 212 and reflect (e.g., by way of TIR) light impacting a side surface of each aperture 206 of LNG 214, also by way of its corresponding ML 212, thereby facilitating a corresponding focusing effect by directing light toward the pyramidal diffusor structure 104 positioned below the corresponding aperture 206 of LNG 214.

Photosensitive region 103 may be a continuous semiconductor region (e.g., a doped semiconductor, such as doped silicon or doped germanium) that may produce electrical charge in response to received photons being absorbed therein. Photosensitive region 103 may be employed as at least a portion of a photodetector (e.g., a photodiode, a phototransistor, or the like). In some embodiments, photosensitive region 103 may occupy less than an entirety of the volume depicted for photosensitive region 103 in FIG. 2A and other figures discussed below (e.g., as indicated by the dashed box in the figures) while possibly remaining in a continuous configuration (e.g., not separated into discrete portions). In the case of the photodetector being a photodiode, for example, the dashed box may be a p-doped portion, while another portion outside the dashed box may be an n-doped portion, thus forming the photodiode. Other configurations of photodetectors are also possible.

To promote internal reflection of light therein, photosensitive region 103 may be surrounded below and laterally by a dielectric material 230 (e.g., SiO₂, SiOₓ, or another dielectric material). In addition, within dielectric material 230 may be disposed a deep trench insertion (DTI) 216 laterally surrounding photosensitive region 103. In some embodiments, DTI 216 may be a metallic material (e.g., copper, aluminum, or the like), a dielectric material (e.g., SiO₂), polycrystalline silicon, or another material. Also, in some embodiments, DTI 216 may be capped with a metal cap 218 or strip (e.g., copper, aluminum, or the like). Other embodiments described below may include similar structures, as depicted in the corresponding figures.

Further, as illustrated in FIG. 2A, a conductive structure 220 may be disposed below, and electrically connected to, photosensitive region 103. As illustrated in FIG. 2A, conductive structure 220 may include a number of conductive contacts or vias 222 interconnecting various conductive layers 224. Further, in some embodiments, the vias 222 and conductive layers 224 may be disposed within one or more layers of dielectric material 230, which in turn may be separated by one or more etch stop layers 226. In some embodiments, conductive structure 220 may form part of a transfer transistor for transferring charge provided by photosensitive region 103 to a processing circuit. Conductive structure 220 may be employed in other embodiments, as depicted in additional figures described below.

In view of the embodiments of FIGS. 2A and 2B, light received from above may be received at each focusing portion 108 of focusing structure 106 that includes an ML 212 and associated portion of LNG 214 and focused at a corresponding pyramidal diffusor structure 104 located therebelow. Pyramidal diffusor structure 104 may then redirect the received light within photosensitive region 103 to promote absorption, thereby improving QE and associated image quality, as described above in connection with FIGS. 1A-1C.

In addition, other sets of embodiments providing the same or similar benefits to the embodiments of FIGS. 2A and 2B are discussed hereafter. For example, FIGS. 3A and 3B illustrate cross-sectional and top views, respectively, of some embodiments of a single-pixel image sensor structure 101B employing a two-by-two array of single pyramidal diffusor structures 104, an LNG 214, and an array of MLs 212, according to the present disclosure. In contrast to the embodiments of FIGS. 2A and 2B, four (instead of nine) MLs 212 and associated pyramidal diffusor structures 104 are deployed in a two-by-two array. Accordingly, in some embodiments, larger (e.g., wider) MLs 212, pyramidal diffusor structures 104, and associated apertures 206 of LNG 214 may be employed in pixel structure 101B relative to the pixel structure 101A of FIGS. 2A and 2B while maintaining a relatively sparse footprint by pyramidal diffusor structures 104 in the plan view of FIG. 2B. However, in such embodiments of pixel structure 101B, a similar focusing effect may be provided by focusing structure 106 and a corresponding diffusion effect may be provided by pyramidal diffusor structures 104 to enhance QE and image quality in a manner similar to that described above for pixel structure 101A. In yet other embodiments, the arrays of MLs 212, LNG 214 apertures 206, and pyramidal diffusor structures 104 may be configured in other ways (e.g., four-by-four, five-by-five, three-by-four, four-by-five, etc.).

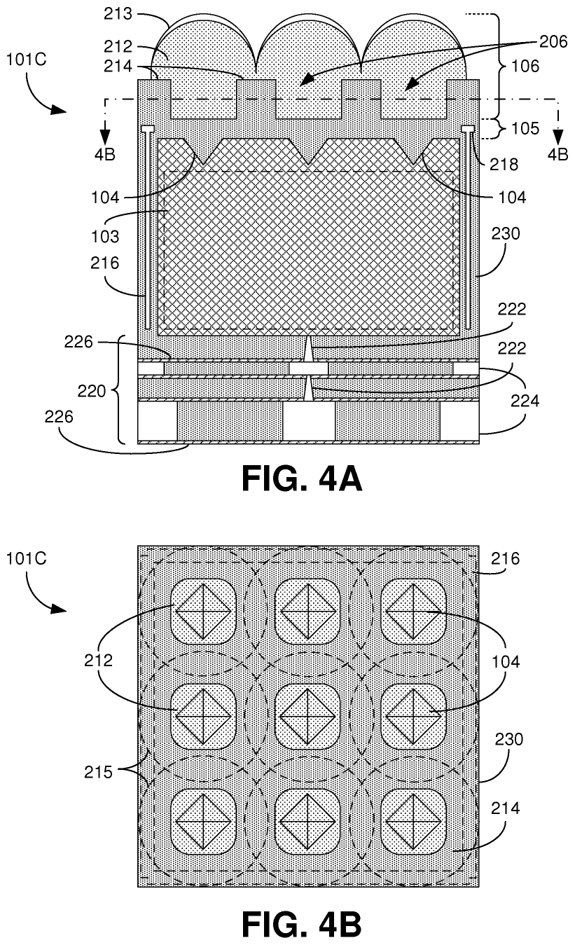

FIGS. 4A and 4B illustrate cross-sectional and top views, respectively, of some embodiments of a single-pixel image sensor structure 101C employing a three-by-three array of rotated single pyramidal diffusor structures 104, an LNG 214, and an array of MLs 212, according to the present disclosure. In a configuration similar to that of pixel structure 101A of FIGS. 2A and 2B, pixel structure 101C includes nine MLs and associated single pyramidal diffusor structures 104. However, in pixel structure 101C, single pyramidal diffusor structures 104 are rotated about their principal (e.g., vertical) axes (e.g., by 45 degrees) relative to single pyramidal diffusor structures 104 of pixel structure 101A. In some embodiments, this rotation may thus alter the path taken within photosensitive region 103 by the photons that are redirected by rotated single pyramidal diffusor structures 104. However, a similar increase in QE and image quality may be accomplished by way of the configuration of rotated single pyramidal diffusor structures 104.

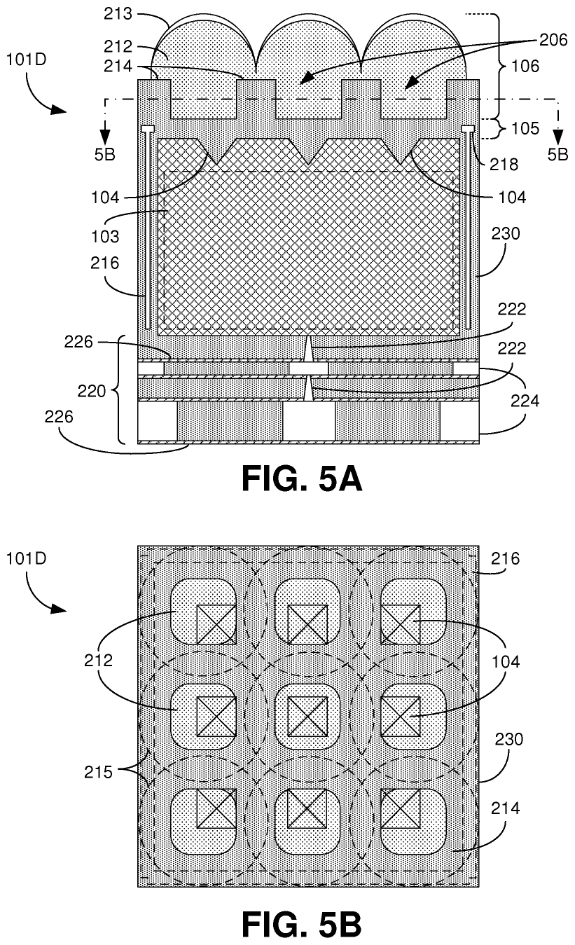

FIGS. 5A and 5B illustrate cross-sectional and top views, respectively, of some embodiments of a single-pixel image sensor structure 101D employing a three-by-three array of laterally-shifted single pyramidal diffusor structures 104, an LNG 214, and an array of MLs 212, according to the present disclosure. In some embodiments, pixel structure 101D varies from pixel structure 101A of FIGS. 2A and 2B in that at least some of the nine single pyramidal diffusor structures 104 are not centered in a plan view beneath its corresponding ML 212 and aperture 206 of LNG 214. More specifically, in pixel structure 101D, each of the eight outer single pyramidal diffusor structures 104 are positioned closer to the central single pyramidal diffusor structures 104 relative to those of pixel structure 101A. However, each of the single pyramidal diffusor structures 104 remains under its associated ML 212 and aperture 206 of LNG 214, thus providing similar QE and image benefits relative to those of pixel structure 101A. In other embodiments, positions of pyramidal diffusor structures 104 other than those depicted in FIGS. 5A and 5B while remaining somewhat under their associated MLs 212 and LNG 214 apertures 206 are also possible.

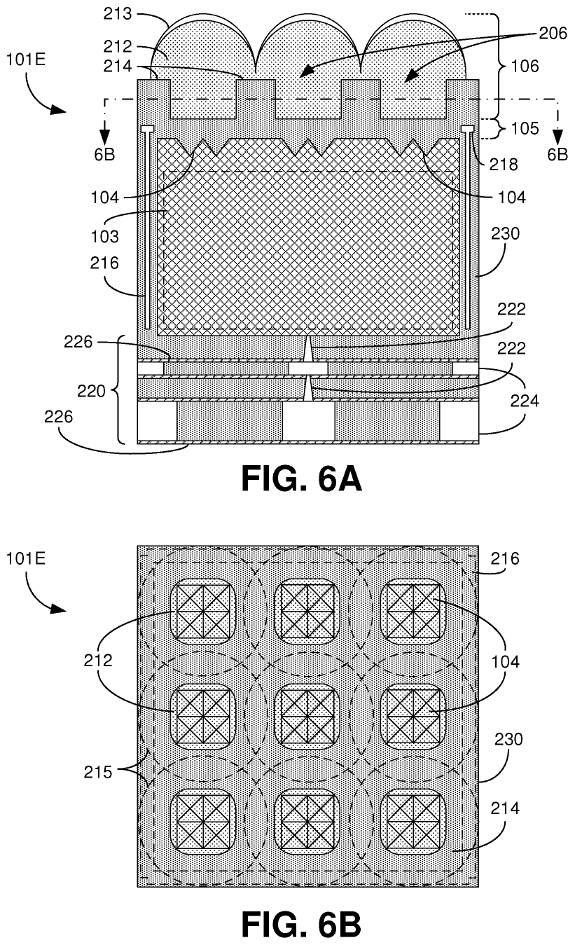

FIGS. 6A and 6B illustrate cross-sectional and top views, respectively, of some embodiments of a single-pixel image sensor structure 101E employing a three-by-three array of multiple pyramidal diffusor structures 104, an LNG 214, and an array of MLs 212, according to the present disclosure. More specifically, instead of a single pyramidal diffusor structure 104 being optically coupled with each ML 212, multiple (e.g., four) pyramidal diffusor structures 104 may be grouped together under each ML 212. In some embodiments, the pyramidal diffusor structures 104 of each group may be adjacent each other (e.g., in a two-by-two array pattern), while in other embodiments, one or more of the pyramidal diffusor structures 104 of each group may be spaced apart. Also, while FIG. 6B depicts each group of pyramidal diffusor structures 104 as centered in a plan view under its corresponding ML 212 and associated LNG 214 aperture 206, other positions for the pyramidal diffusor structures 104 under the corresponding ML 212 and associated LNG 214 aperture 206 are also possible. In addition, each of the pyramidal diffusor structures 104 of each group are shown as being of the same size, while such a limitation may not be employed in other embodiments.

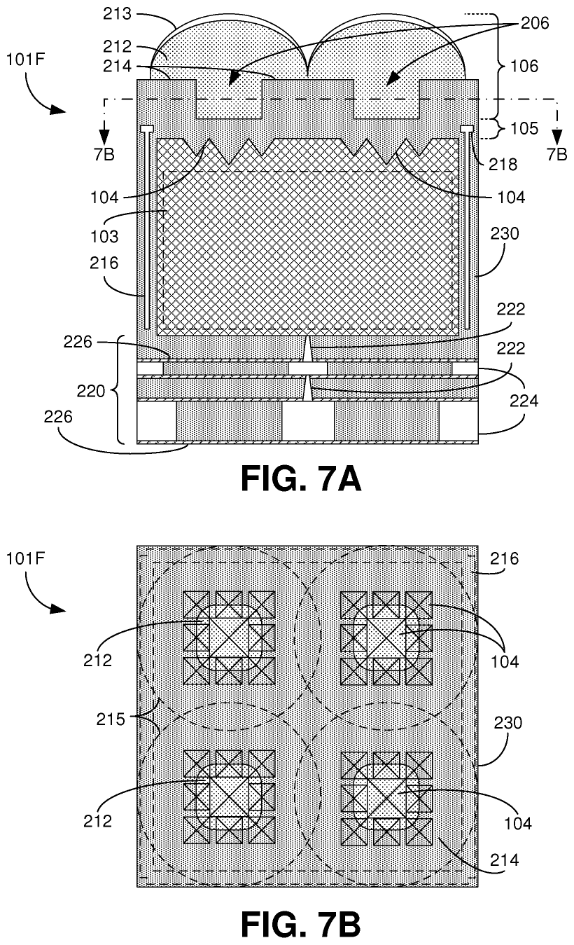

FIGS. 7A and 7B illustrate cross-sectional and top views, respectively, of some embodiments of a single-pixel image sensor structure 101F employing a two-by-two array of multiple pyramidal diffusor structures 104, an LNG 214, and an array of MLs 212, according to the present disclosure. More specifically, multiple (e.g., nine) pyramidal diffusor structures 104 may be grouped together under each ML 212. In some embodiments, at least some of the pyramidal diffusor structures 104 may be spaced apart from each other. Also, as depicted in FIG. 7B, in some embodiments, a centrally positioned pyramidal diffusor structure 104 of each group is larger than the eight remaining pyramidal diffusor structures 104. Further, significant portions of the eight remaining pyramidal diffusor structures 104 are not positioned under its associated aperture 206 of LNG 214. In such embodiments, the eight remaining pyramidal diffusor structures 104 may serve to redirect photons at a periphery of the corresponding aperture 206 of LNG 214.

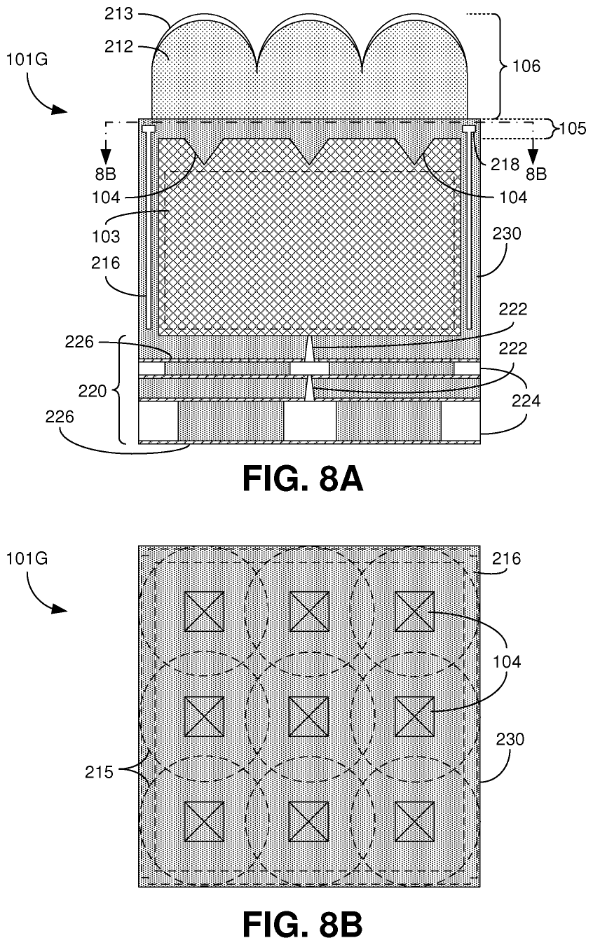

FIGS. 8A and 8B illustrate cross-sectional and top views, respectively, of some embodiments of a single-pixel image sensor structure 101G employing a three-by-three array of single pyramidal diffusor structures 104 and an array of MLs 212, according to the present disclosure. More specifically, in some embodiments, pixel structure 101G does not include an LNG in association with MLs 212, thus relying on MLs 212 to performing the focusing functionality of the focusing structure 106. In some embodiments, forgoing an LNG in focusing structure 106 may simplify the fabrication of pixel structure 101G while providing QE and image quality improvements similar to those discussed above.

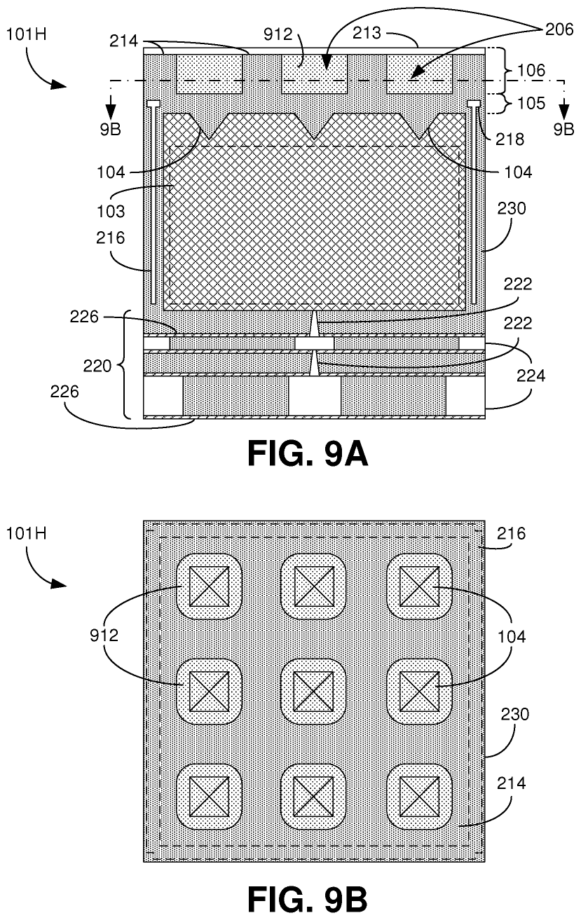

FIGS. 9A and 9B illustrate cross-sectional and top views, respectively, of some embodiments of a single-pixel image sensor structure 101H employing a three-by-three array of single pyramidal diffusor structures 104 and an LNG 214, according to the present disclosure. Accordingly, in some embodiments, pixel structure 101H does not include an array of MLs in association with LNG 214, thus relying on LNG 214 to performing the focusing functionality of the focusing structure 106. In some embodiments, the apertures 206 of LNG 214 may be filled with a dielectric material 912 that otherwise may be employed in a microlens, as described above. Further, in some embodiments, an antireflective coating 213 may be disposed over LNG 214 and the dielectric material 912. In a manner similar to that of pixel structure 101G, forgoing an ML array in focusing structure 106 for such embodiments may simplify the fabrication of pixel structure 101H while providing QE and image quality improvements similar to those of other embodiments described above.

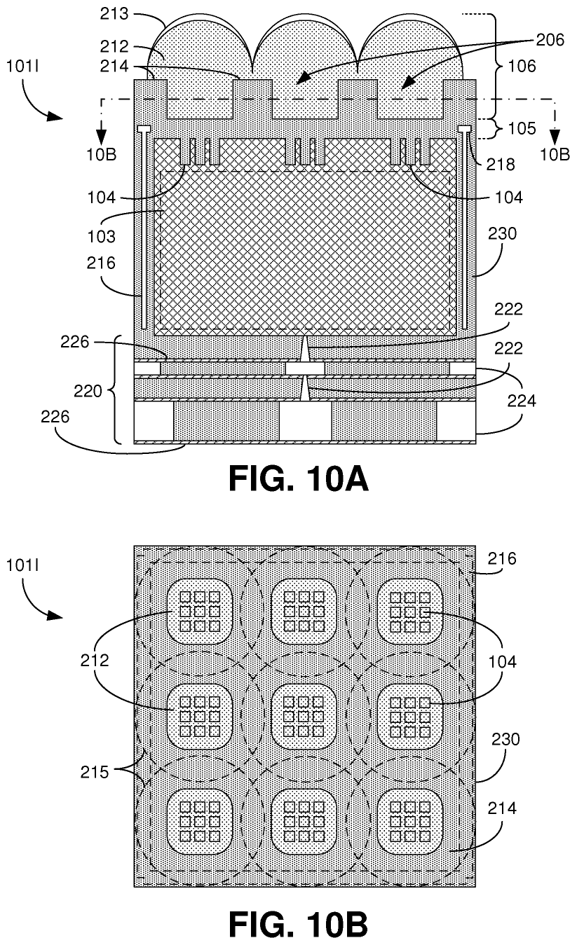

FIGS. 10A and 10B illustrate cross-sectional and top views, respectively, of some embodiments of a single-pixel image sensor structure 101I employing a three-by-three array of multiple columnar diffusor structures 104, an LNG 214, and an array of MLs 212, according to the present disclosure. In some embodiments, the columnar diffusor structures 104 are arranged into groups of nine columnar diffusor structures 104 in a three-by-three array pattern, with each columnar diffusor structure 104 being spaced apart from, and having the same size and length as, other columnar diffusor structures 104 of the group. In other embodiments, different numbers of columnar diffusor structures 104 may be employed in each group. Further, each columnar diffusor structure 104 in some embodiments may be a shallow trench into which dielectric material (e.g., SiO₂, SiOₓ, or another dielectric material) is disposed.

In some embodiments, each of the columnar diffusor structures 104 are rectangular in the cross-section of FIG. 10A and square in the plan view of FIG. 10B. Accordingly, in some embodiments, each columnar diffusor structure 104 includes a planar surface facing downward. However, as described below, other shapes of columnar diffusor structures 104 may be used in other embodiments. In each case, light focused into each group of columnar diffusor structures 104 by focusing structure 106 may be redirected or diffused in a manner similar to that provided by the pyramidal diffusor structures discussed above.

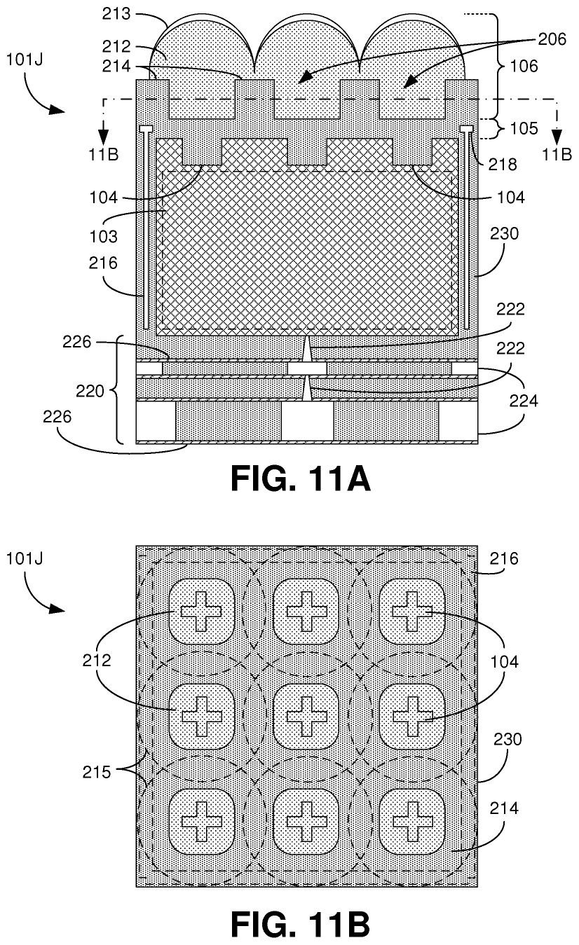

FIGS. 11A and 11B illustrate cross-sectional and top views, respectively, of some embodiments of a single-pixel image sensor structure 101J employing a three-by-three array of single columnar diffusor structures 104, an LNG 214, and an array of MLs 212, according to the present disclosure. In some embodiments, each columnar diffusor structure 104 is rectangular in the cross-section of FIG. 11A and cross-shaped in the plan view of FIG. 11B.

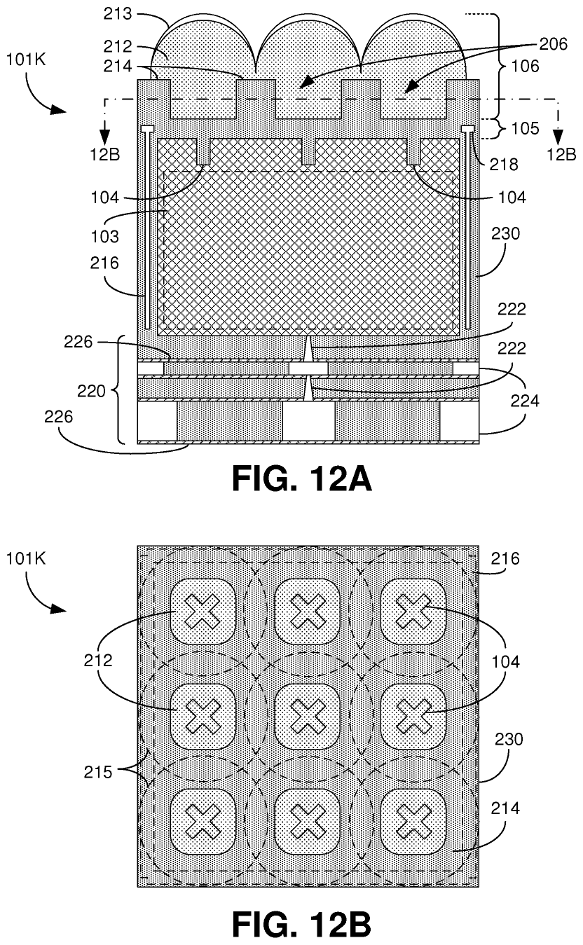

FIGS. 12A and 12B illustrate cross-sectional and top views, respectively, of some embodiments of a single-pixel image sensor structure 101K employing a three-by-three array of rotated single columnar diffusor structures 104, an LNG 214, and an array of MLs 212, according to the present disclosure. As illustrated, each columnar diffusor structure 104 possesses the same shape as those shown in FIGS. 11A and 11B, but is rotated about its vertical axis by 45 degrees. Consequently, the paths within photosensitive region 103 along which photons are redirected in pixel structure 101K are different from those associated with pixel structure 101J while providing similar enhancements in QE and image quality.

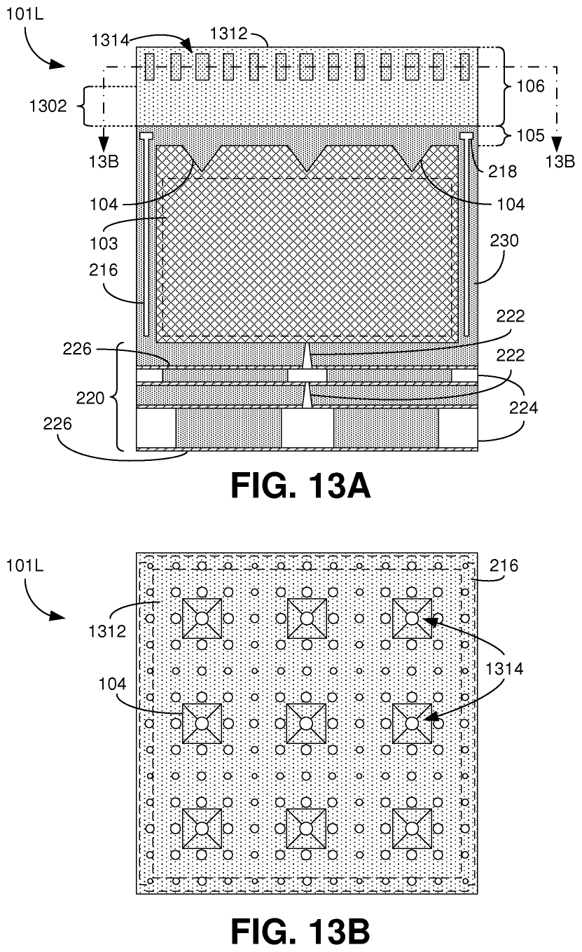

FIGS. 13A through 18B describe some embodiments in which focusing structure 106 includes an array of planar lenses in lieu of MLs 212 employed in some embodiments discussed above, thus providing a focusing functionality while possibly reducing the overall height of focusing structure 106. For example, FIGS. 13A and 13B illustrate cross-sectional and top views, respectively, of some embodiments of a single-pixel image sensor structure 101L employing a three-by-three array of single pyramidal diffusor structures 104 and an array of meta-lenses 1314, according to the present disclosure. As illustrated, in some embodiments, each meta-lens 1314 includes a plurality of vertically oriented columns or pillars (e.g., cylindrical columns) with constant height and lateral spacing (e.g., arranged as an array), but with varying diameter. Each of the columns or pillars may operate as a waveguide such that each column, in combination with surrounding columns, performs a focusing functionality for a pyramidal diffusor structure 104 optically coupled with each meta-lens 1314. Further, the columns may be disposed within a substrate 1312. Also, as shown in FIG. 13A, a portion of substrate 1312 may form a spacer 1302 between meta-lens 1314 and dielectric layer 105. In some embodiments, the columns or pillars and substrate 1312 may include dielectric materials (e.g., SiO₂, SiOₓ, or another dielectric material) of varying refractive indices to support the focusing function. However, other materials may be employed for both the pillars and substrate 1312 in other embodiments. Further, in some embodiments, the width (e.g., viewed as a critical dimension) and spacing of the pillars may be based on particular limits imposed on those parameters by the particular process technology being employed.

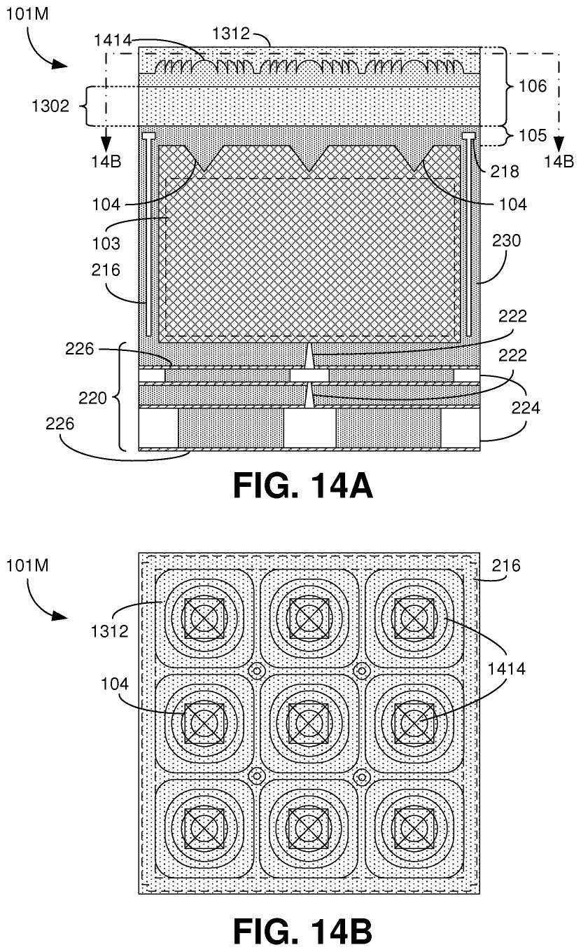

FIGS. 14A and 14B illustrate cross-sectional and top views, respectively, of some embodiments of a single-pixel image sensor structure 101M employing a three-by-three array of single pyramidal diffusor structures 104 and an array of Fresnel lenses 1414, according to the present disclosure. In some embodiments, each Fresnel lens 1414 may include a plurality of concentric segments having upper surfaces that replicate a corresponding portion of a refractive lens, such as a microlens. Consequently, as with meta-lens 1314, use of a Fresnel lens 1414 in lieu of a microlens may provide similar focusing functionality while reducing the overall height of focusing structure 106. Further, each Fresnel lens 1414 may be coupled with a corresponding pyramidal diffusor structure 104.

Also, in some embodiments, the array of Fresnel lenses 1414 may be disposed within a substrate 1312. Moreover, substrate 1312 may also include a spacer 1302 to facilitate the focusing of light by each Fresnel lens 1414 to its associated pyramidal diffusor structure 104. Also, as with other embodiments described above, the array of Fresnel lenses 1414 and the associated spacer 1302 are disposed over dielectric layer 105 and pyramidal diffusor structures 104. In some embodiments, the array of Fresnel lenses 1414 and substrate 1312 may include dielectric materials or other materials of varying refractive indices to support the focusing function.

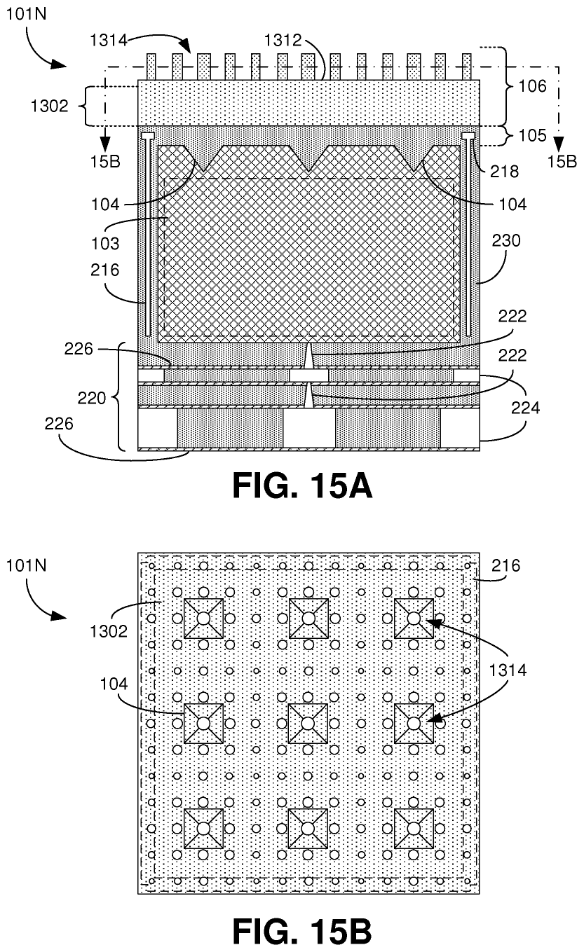

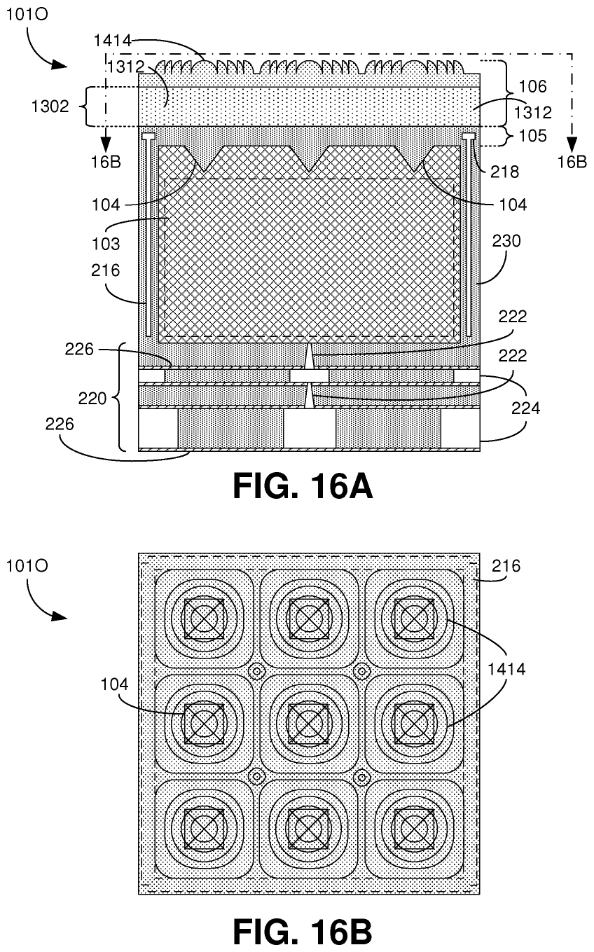

FIGS. 15A and 15B illustrate cross-sectional and top views, respectively, of some embodiments of another single-pixel image sensor structure 101N employing a three-by-three array of single pyramidal diffusor structures 104 and an array of meta-lenses 1314, according to the present disclosure. More specifically, unlike pixel structure 101L of FIGS. 13A and 13B, pixel structure 101N includes an array of meta-lenses 1314 disposed over (as opposed to inside) substrate 1312. Similarly, FIGS. 16A and 16B illustrate cross-sectional and top views, respectively, of some embodiments of a single-pixel image sensor structure 101O employing a three-by-three array of single pyramidal diffusor structures 104 and an array of Fresnel lenses 1414, according to the present disclosure. Unlike pixel structure 101M of FIGS. 14A and 14B, pixel structure 101O includes an array of Fresnel lenses 1414 disposed over (as opposed to inside) substrate 1312.

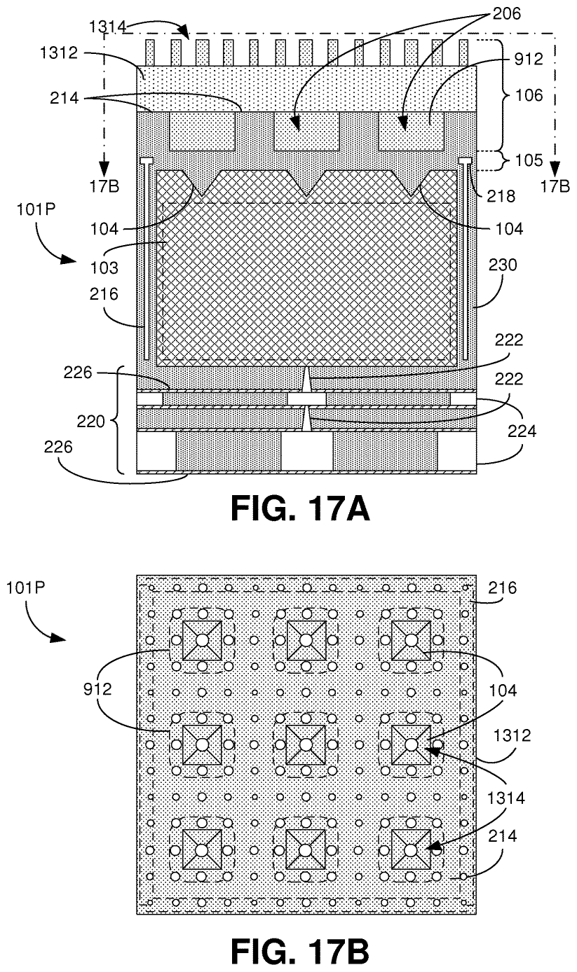

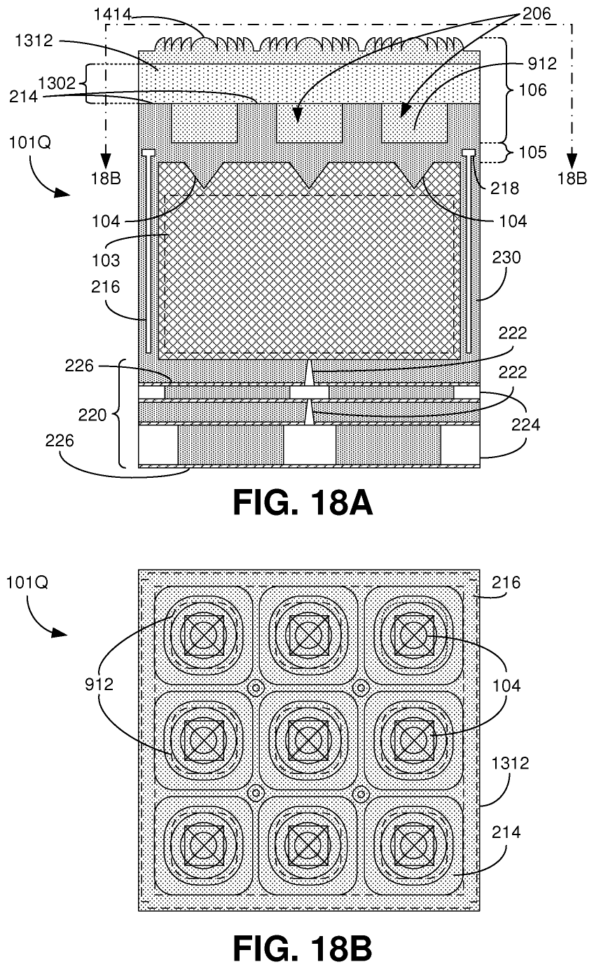

FIGS. 17A and 17B illustrate cross-sectional and top views, respectively, of some embodiments of another single-pixel image sensor structure 101P employing a three-by-three array of single pyramidal diffusor structures 104, an LNG 214, and an array of meta-lenses 1314, according to the present disclosure. Similarly, FIGS. 18A and 18B illustrate cross-sectional and top views, respectively, of some embodiments of a single-pixel image sensor structure 101Q employing a three-by-three array of single pyramidal diffusor structures 104, an LNG 214, and an array of Fresnel lenses 1414, according to the present disclosure. In some embodiments of pixel structures 101P and 101Q, an LNG 214 is disposed over dielectric layer 105 and under substrate 1312 serving as a spacer 1302. In some embodiments, LNG 214 includes a dielectric material (e.g., SiO₂, SiOₓ, or another dielectric material), and the apertures 206 of LNG 214 may be filled with another dielectric material 912. In some embodiments, dielectric material 912 filling the apertures 206 of LNG 214 may possess a diffractive index greater than 1.5, while LNG 214 may include a dielectric material with a diffractive index less than 1.5. In some embodiments, use of these diffractive indexes may result in total internal reflection of light from a meta-lens 1314 or Fresnel lens 1414, via spacer 1302, at an interface of dielectric material 912 and sidewall of LNG 214 toward a corresponding pyramidal diffusor structure 104.

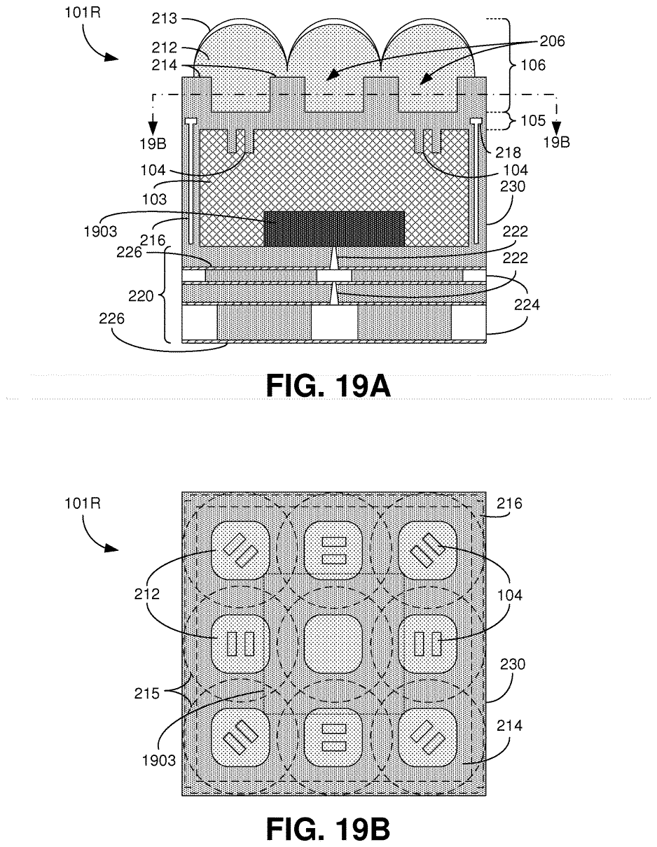

FIGS. 19A and 19B illustrate cross-sectional and top views, respectively, of some embodiments of a single-pixel image sensor structure 101R employing a partially empty three-by-three array of multiple columnar diffusor structures 104, an LNG 214, and an array of MLs 212, according to the present disclosure. In some embodiments, photosensitive region 103 may include a short-wave infrared (SWIR)-sensitive region 1903 (e.g., germanium) for SWIR imaging applications. As shown, SWIR-sensitive region 1903 may be shorter in the cross-section of FIG. 19A and narrower in the plan view of FIG. 19B than the entirety of photosensitive region 103. Consequently, columnar diffusor structures 104 may be configured to direct a significant amount of light received by way of MLs 212 to SWIR-sensitive region 1903.

In some embodiments, columnar diffusor structures 104 may be rectangular in cross-section and plan view, and may be arranged such that a wide lateral face of each columnar diffusor structure 104 faces a center of photosensitive region 103. Consequently, as illustrated in FIG. 19B, columnar diffusor structures 104 positioned along each side of photosensitive region 103 are oriented parallel to that side, while columnar diffusor structures 104 positioned in the corners of photosensitive region 103 are oriented at a 45-degree angle to the sides of photosensitive region 103. Further, columnar diffusor structures 104 may be arranged in groups of two columnar diffusor structures 104 in parallel with each other, where each group is optically coupled with a corresponding ML 212. Further, in some embodiments, no columnar diffusor structures 104 may be optically coupled with a center-positioned ML 212 (e.g., centrally positioned over SWIR-sensitive region 1903) to facilitate the passing of at least some light from the associated ML 212 and aperture 206 of LNG 214 directly toward SWIR-sensitive region 1903.

While the various embodiments of FIGS. 2A through 19B are described in view of particular combinations of structures (e.g., focusing structures 106, diffusor structures 104, and so on), other combinations of structures not specifically illustrated in FIGS. 2A through 19B are also possible. For example, while planar lenses (e.g., meta-lenses 1314 and Fresnel lenses 1414) are depicted in FIGS. 13A through 18B in conjunction with a three-by-three array of single pyramidal diffusor structures 104, other diffusor structures (e.g., groups of multiple pyramidal diffusor structures, columnar diffusor structures in various configurations, and so on) discussed herein may be employed with the planar lenses in other embodiments not explicitly illustrated herein. Other such combinations of the various components of a pixel structure are also possible.

As a result of such embodiments, the resulting pixel structure may include focusing structures that focus received light to corresponding groups of one or more light diffusors, thus allowing for areas over the photosensitive region to remain uncovered by the light diffusors. As a result, much of the received light may be redirected to enhance photon absorption within the photosensitive region, and less light may escape the pixel structure by way of the light diffusors, as more photons may impact surfaces between the light diffusors at angles that promote TIR, as described above. Moreover, in some embodiments, by employing the plurality of light-focusing portions of the light-focusing structure, the overall thickness or height of the light-focusing structure may be reduced.

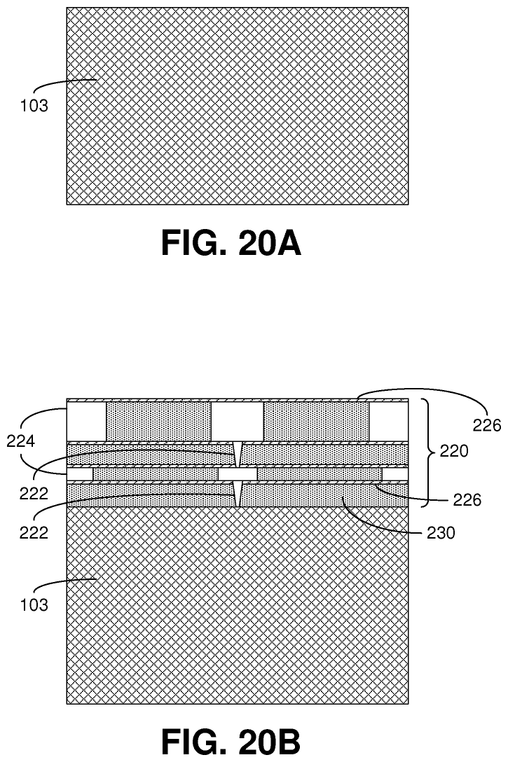

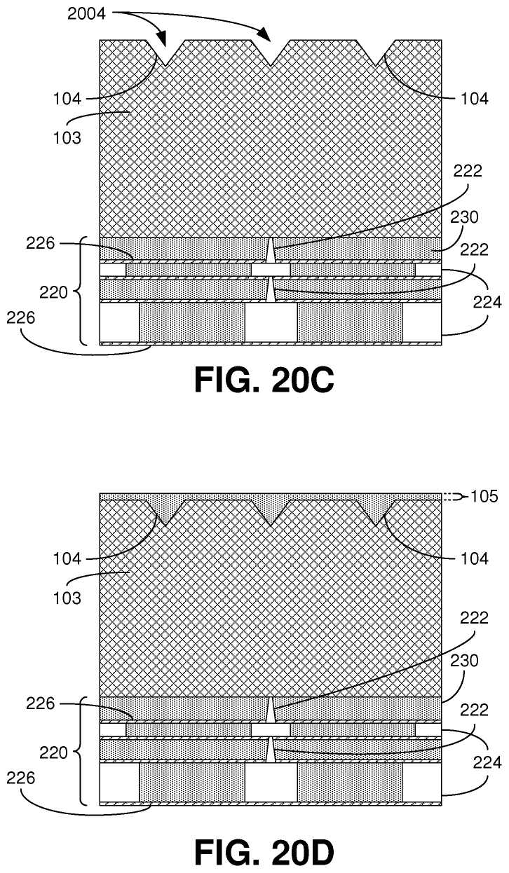

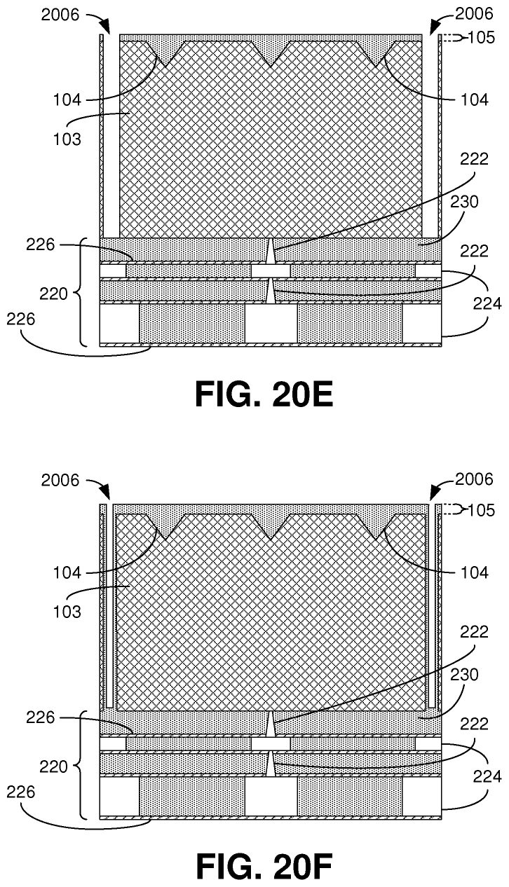

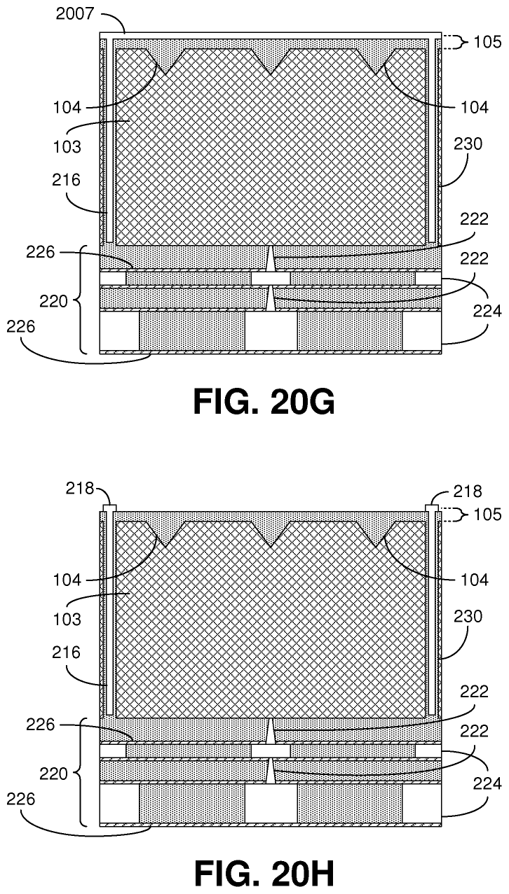

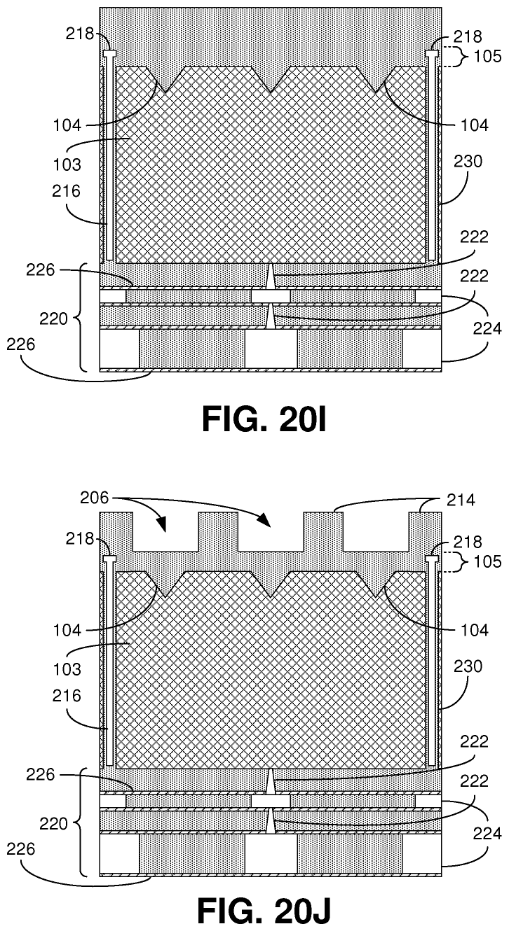

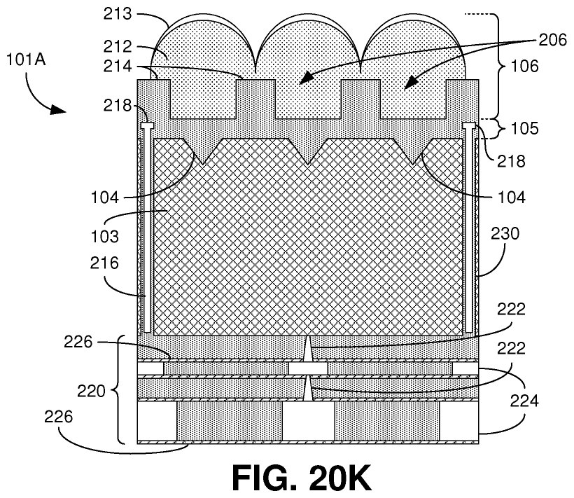

FIGS. 20A through 20K illustrate cross-sectional side views of some embodiments of an IC device including a single-pixel image sensor structure (particularly, pixel structure 101A illustrated in FIGS. 2A and 2B) at various stages of manufacture, according to the present disclosure. Although FIGS. 20A through 20K are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

FIG. 20A illustrates a photosensitive region 103 upon which other features of pixel structure 101A may be fabricated. In some embodiments, photosensitive region 103 may be at least part of a semiconductor layer (e.g., silicon, germanium, or another semiconductor material). Further, photosensitive region 103 may be doped or implanted to produce a doped photosensitive region 103 (e.g., an n-doped region within p-doped silicon). Also, while the layer of FIG. 20A is labeled as photosensitive region 103, in some embodiments only a continuous portion of the volume shown in FIG. 20A may actually include photosensitive region 103.

FIG. 20B illustrates the forming (e.g., deposition, etching, and/or the like) of a conductive structure 220 over a front side (e.g., a first side) of photosensitive region 103. In some embodiments, conductive structure 220 is formed within one or more layers of dielectric material 230, where adjacent layers of dielectric material 230 may be separated by an etch stop layer 226. Further, conductive structure 220 may include one or more conductive layers 224 interconnected with contacts or vias 222. Also, in some embodiments, conductive structure 220 may be electrically connected to photosensitive region 103 (e.g., to transfer charge collected in photosensitive region 103 as a result of absorbed photons, such as to a processing circuit for generating an image).

FIG. 20C illustrates the removal (e.g., etching) of regions 2004 at an upper surface of photosensitive region 103 in which diffusor structures (e.g., pyramidal diffusor structures 104 of FIGS. 2A and 2B) are to be formed.

FIG. 20D illustrates the forming (e.g., deposition) of pyramidal diffusor structures 104 and at least a portion of dielectric layer 105 over photosensitive region 103. In some embodiments, pyramidal diffusor structures 104 and dielectric layer 105 may be formed from the same dielectric material (e.g., SiO₂, SiOₓ, or another dielectric material).

FIG. 20E illustrates the removal (e.g., etching) of trenches 2006 through dielectric layer 105 and photosensitive region 103, where a deep trench insertion (DTI) may be formed therein. In some embodiments, such as when an IC device includes an array of pixel structures 101A, such trenches 2006 may form multiple (e.g., an array of) adjacent photosensitive volumes in photosensitive region 103.

FIG. 20F illustrates the forming (e.g., deposition) of additional dielectric material 230 conformally within trenches 2006 and along a top of previously formed dielectric layer 105.

FIG. 20G illustrates the forming (e.g., deposition) of a deep trench insertion (DTI) 216 within remaining portions of trenches 2006 and an associated metal layer 2007 over dielectric layer 105. In some embodiments, metal layer 2007 may be copper, aluminum, or another metal or metal alloy. Also, in some embodiments, DTI 216 may be a metal (e.g., the same metal as metal layer 2007), a dielectric material (e.g., SiO₂), or polycrystalline silicon.

FIG. 20H illustrates the forming (e.g., etching) of metal layer 2007 to form a metal cap 218 for each DTI 216. In some embodiments, DTI 216 and metal cap 218 may form a wall around photosensitive region 103 to retain photons entering photosensitive region 103 as well as prevent entry of photons from nearby photosensitive regions 103 of other pixels.

FIG. 20I illustrates the forming (e.g., deposition) of additional dielectric material 230 over pyramidal diffusor structures 104 and metal cap 218, such as to complete dielectric layer 105 and provide material for LNG 214. In some embodiments, additional dielectric material 230 may match other dielectric material (e.g., SiO₂) previous deposited about photosensitive region 103.

FIG. 20J illustrates the forming (e.g., etching) of apertures 206 to complete the fabrication of LNG 214. FIG. 20K illustrates the forming (e.g., deposition and/or application) of MLs 212 (and possibly antireflective coating 213) in apertures 206 and over LNG 214. In some embodiments, MLs 212 may include a dielectric material that has a high refractive index relative to LNG 214 and that is highly transparent for the target wavelength range (e.g., in the NIR band, the SWIR band, or the like). Also, in some embodiments, MLs 212 may include wavelength filter material such that unwanted photons associated with wavelength bands that are not of interest are blocked. In some embodiments, all of MLs 212, or only the base portions of MLs 212 (e.g., those portions disposed within apertures 206), may include the wavelength filter material. In some embodiments, antireflective coating 213 may also be a dielectric material (e.g., SiO₂).

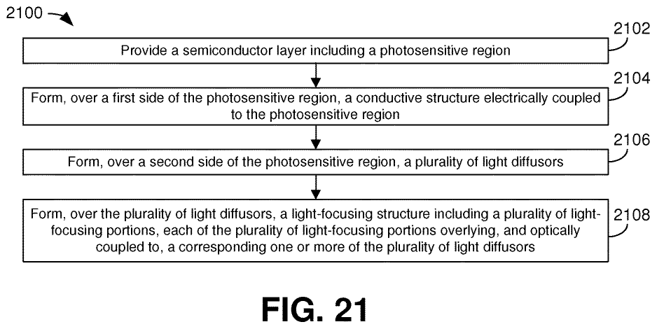

FIG. 21 illustrates a methodology 2100 of forming an IC device including a single-pixel image sensor structure, in accordance with some embodiments. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

Acts 2102 through 2108 may correspond, for example, to the structure previously illustrated in FIGS. 20A through 20K in some embodiments. However, methodology 2100 may also be applicable to other embodiments of pixel structures described above. At Act 2102, for example, a semiconductor layer is provided that includes a photosensitive region (e.g., photosensitive region 103 of FIGS. 2A and 2B). FIG. 20A illustrates a cross-sectional view of some embodiments corresponding to Act 2102.

At Act 2104, a conductive structure (e.g., conductive structure 220 of FIG. 2A) electrically coupled to the photosensitive region is formed over a front (or first) side of the photosensitive region. FIG. 20B illustrates a cross-sectional view of some embodiments corresponding to Act 2104.

At Act 2106, a plurality of light diffusors (e.g., pyramidal diffusor structures 104 of FIGS. 2A and 2B) may be formed over a back (or second) side of the photosensitive region. FIGS. 20C and 20D illustrate cross-sectional views of some embodiments corresponding to Act 2106.

At Act 2108, a light-focusing structure (e.g., light-focusing structure 106 of FIGS. 2A and 2B) including a plurality of light-focusing portions (e.g., MLs 212, meta-lenses 1314, Fresnel lenses 1414, and/or portions of LNG 214) is formed over the plurality of light diffusors. Each of the plurality of light-focusing portions is optically coupled to a corresponding one or more of the plurality of light diffusors. FIGS. 20I through 20K illustrate cross-sectional views of some embodiments corresponding to Act 2108.

Some embodiments relate to an IC device. The IC device includes a semiconductor layer, a pixel including a photodetector in the semiconductor layer, a conductive structure electrically coupled to the pixel on a first side of the semiconductor layer, a plurality of light diffusors overlying the photodetector on a second side of the semiconductor layer opposite the first side, and a light-focusing structure overlying the plurality of light diffusors. The light-focusing structure includes a plurality of light-focusing portions. Each of the plurality of light-focusing portions overlies, and is configured to focus light on, a corresponding one or more of the plurality of light diffusors.

Some embodiments relate to another IC device. The IC device includes an array of single-pixel image sensor structures. Each single-pixel image sensor structure includes a semiconductor layer having a photosensitive region; a reflective barrier laterally surrounding the photosensitive region; a conductive structure disposed on, and electrically coupled to, a first side of the photosensitive region; a plurality of light diffusor groups disposed on a second side of the semiconductor layer and laterally separated from each other, each of the plurality of light diffusor groups including one or more light diffusors; a dielectric layer disposed on the plurality of light diffusor groups; and a light-focusing structure disposed on the dielectric layer. The light-focusing structure includes a plurality of light-focusing portions. Each of the plurality of light-focusing portions overlies a corresponding one of the plurality of light diffusor groups. Each of the plurality of light-focusing portions includes at least one of a lens or a portion of a low-refractive-index grid surrounding one of a plurality of apertures of the low-refractive-index grid.

Some embodiments relate to a method. The method includes: providing a semiconductor layer that includes a photosensitive region; forming, over a first side of the photosensitive region, a conductive structure electrically coupled to the photosensitive region; forming, over a second side of the photosensitive region, a plurality of light diffusors; and forming, over the plurality of light diffusors, a light-focusing structure including a plurality of light-focusing portions. Each of the plurality of light-focusing portions overlies, and is optically coupled to, a corresponding one or more of the plurality of light diffusors.

It will be appreciated that in this written description, as well as in the claims below, the terms “first”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a semiconductor layer;
a pixel comprising a photodetector in the semiconductor layer;
a conductive structure electrically coupled to the pixel on a first side of the semiconductor layer;
a plurality of light diffusors overlying the photodetector on a second side of the semiconductor layer opposite the first side; and
a light-focusing structure overlying the plurality of light diffusors, the light-focusing structure comprising a plurality of light-focusing portions, each of the plurality of light-focusing portions overlying, and configured to focus light on, a corresponding one or more of the plurality of light diffusors.

2. The IC device of claim 1, wherein each of the plurality of light diffusors extends into the semiconductor layer.

3. The IC device of claim 1, wherein each of the plurality of light-focusing portions overlies, and is configured to focus light on, a corresponding single one of the plurality of light diffusors.

4. The IC device of claim 3, wherein each of the plurality of light diffusors comprises a pyramidal structure having an apex directed toward the first side of the semiconductor layer.

5. The IC device of claim 3, wherein each of the plurality of light diffusors comprises a columnar structure having a planar surface facing the first side of the semiconductor layer.

6. The IC device of claim 1, wherein the plurality of light diffusors are grouped into a plurality of groups of light diffusors, each of the plurality of groups of light diffusors optically coupled with a corresponding one of the plurality of light-focusing portions.

7. The IC device of claim 6, wherein each of the plurality of groups of light diffusors comprises a plurality of pyramidal structures, each of the plurality of pyramidal structures having an apex directed toward the first side of the semiconductor layer.

8. The IC device of claim 7, wherein at least one of the plurality of pyramidal structures has a different size than another one of the plurality of pyramidal structures in a plan view of the IC device.

9. The IC device of claim 6, wherein each of the plurality of groups of light diffusors comprises a plurality of columnar structures, each of the plurality of columnar structures having a planar surface facing the first side of the semiconductor layer.

10. The IC device of claim 1, wherein the light-focusing structure comprises at least one of a plurality of microlenses or a low-refractive-index grid.

11. The IC device of claim 10, wherein each of the plurality of light-focusing portions comprises a corresponding different one of the plurality of microlenses.

12. The IC device of claim 10, wherein each of the plurality of light-focusing portions comprises an aperture of the low-refractive-index grid.

13. The IC device of claim 1, wherein each of the plurality of light-focusing portions comprises a planar lens.

14. The IC device of claim 13, wherein the planar lens comprises one of a meta-lens or a Fresnel lens.

15. An integrated circuit (IC) device, comprising:
an array of single-pixel image sensor structures, each single-pixel image sensor structure comprising:
a semiconductor layer comprising a photosensitive region;
a reflective barrier laterally surrounding the photosensitive region;
a conductive structure disposed on, and electrically coupled to, a first side of the photosensitive region;
a plurality of light diffusor groups disposed on a second side of the semiconductor layer and laterally separated from each other, each of the plurality of light diffusor groups comprising one or more light diffusors;
a dielectric layer disposed on the plurality of light diffusor groups; and
a light-focusing structure disposed on the dielectric layer, the light-focusing structure comprising a plurality of light-focusing portions, each of the plurality of light-focusing portions overlying a corresponding one of the plurality of light diffusor groups, each of the plurality of light-focusing portions comprising at least one of:
a lens; or
a portion of a low-refractive-index grid surrounding one of a plurality of apertures of the low-refractive-index grid.

16. The IC device of claim 15, wherein the lens comprises one of a microlens, a meta-lens, or a Fresnel lens.

17. The IC device of claim 15, wherein each of the one or more light diffusors of each of the plurality of light diffusor groups extends into the semiconductor layer and comprises at least one pyramidal structure or at least one columnar structure.

18. A method, comprising:
providing a semiconductor layer that includes a photosensitive region;
forming, over a first side of the photosensitive region, a conductive structure electrically coupled to the photosensitive region;
forming, over a second side of the photosensitive region, a plurality of light diffusors; and
forming, over the plurality of light diffusors, a light-focusing structure including a plurality of light-focusing portions, each of the plurality of light-focusing portions overlying, and optically coupled to, a corresponding one or more of the plurality of light diffusors.

19. The method of claim 18, wherein forming the plurality of light diffusors comprises:
etching a plurality of voids into a surface of the second side of the photosensitive region, each of the plurality of voids having a shape of each of the plurality of light diffusors; and
forming a dielectric layer over the second side of the photosensitive region, the dielectric layer filling each of the plurality of voids.

20. The method of claim 18, wherein the plurality of light diffusors are arranged over the second side of the photosensitive region as a plurality of groups of light diffusors, wherein each of the plurality of groups of light diffusors comprises one or more of the plurality of light diffusors.
